(19) United States
(12) Patent Application Publication
(10) Pub. No.: US 2016/0276541 A1
(43) Pub. Date: Sep. 22, 2016

(54) Light Emitting Diodes With Current Injection Enhancement From The Periphery

(71) Applicant: Toshiba Corporation, Tokyo (JP)

(72) Inventor: Li Yan, Dublin, CA (US)

(21) Appl. No.: 14/658,942

(22) Filed: Mar. 16, 2015

(51) Int. Cl. H01L 33/38; H01L 33/40

(52) U.S. Cl. CPC H01L 33/385; H01L 33/405; H01L 33/382

(57) ABSTRACT

A light emitting diode (LED) assembly with current injection enhancement from the periphery of the LED is disclosed. In one embodiment, the LED assembly includes an LED comprising a light emitting layer disposed between a first layer having a first conductivity type and a second layer having a second conductivity type. The LED assembly further includes a first electrode and a second electrode. The first electrode is formed on a surface of the first layer opposite the light emitting layer, and electrically coupled to the first layer. The first electrode substantially covers the surface of the first layer. The second electrode is formed at along a portion of the periphery of the LED, outside of a perimeter of the first electrode. The second electrode extends through the first layer and the light emitting layer to the second layer, and is electrically coupled to the second layer. In one embodiment, the LED assembly includes one or more second electrodes along the periphery of the LED. In one embodiment, the one or more second electrodes partially surround the first electrode. In another embodiment, the one or more second electrodes completely surround the first electrode. In yet a further embodiment, the one or more second electrodes extend inwards of the sidewall of the LED.

### FIELD OF THE INVENTION

This invention generally relates to light emitting diode (LED) assemblies, and more particularly, to LED assemblies with current injection enhancement from the periphery of the LED.

### BACKGROUND OF THE INVENTION

In general, light emitting diodes (LEDs) begin with a semiconductor growth substrate, generally a group III-V compound such as gallium nitride (GaN), gallium arsenide (GaAs), gallium phosphide (GaP), indium phosphide (InP), and gallium arsenide phosphide (GaAsP). The semiconductor growth substrate may also be sapphire (Al₂0₃), silicon (Si), and silicon carbide (SiC) for group III-Nitride based LEDs, such as gallium nitride (GaN). Epitaxial semiconductor layers are grown on the semiconductor growth substrate to form the N-type and P-type semiconductor layers of the LED. The epitaxial semiconductor layers may be formed by a number of developed processes including, for example, Liquid Phase Epitaxy (LPE), Molecular-Beam Epitaxy (MBE), and Metal Organic Chemical Vapor Deposition (MOCVD). After the epitaxial semiconductor layers are formed, electrical contacts are coupled to the N-type and P-type semiconductor layers using known photolithography, etching, evaporation, and polishing processes. Individual LEDs are diced and mounted to a package with wire bonding. An encapsulant is deposited onto the LED and the LED is sealed with a protective lens which also aids in light extraction.

There are a number of different types of LED assemblies, including lateral LEDs, vertical LEDs, flip-chip LEDs, and hybrid LEDs (a combination of the vertical and flip-chip LED structure). Typically, flip-chip LED and hybrid LED assemblies utilize a reflective contact between the LED and the underlying substrate or submount to reflect photons which are generated downwards toward the substrate or submount. By using a reflective contact, more photons are allowed to escape the LED rather than be absorbed by the substrate or submount, improving the overall light output power and light output efficiency of the LED assembly.

A conventional flip-chip or hybrid LED assembly is shown in FIGS. 1A and 1B. FIG. 1A is a plan view of an LED assembly 100 in the prior art, and FIG. 1B is a cross-sectional view of the LED assembly 100 of FIG. 1A taken along the axis AA. In FIG. 1A, a plurality of N-electrodes 110, or vias, are formed in a patterned grid in the LED 101 of the LED assembly 100. As shown in FIG. 1B, the plurality of N-electrodes 110 are electrically coupled to an N-type semiconductor layer 102 of LED 101. The plurality of N-electrodes 110 extend through the P-type semiconductor layer 104 and the light emitting layer 106 to reach the N-type semiconductor layer 102 so that the plurality of N-electrodes 110 contact the N-type semiconductor layer 102. Underlying the N-type semiconductor layer 102 of the LED 101 is light emitting layer 106 and P-type semiconductor layer 104. A P-electrode 114 is formed under the LED 101 and electrically coupled to the P-type semiconductor layer 104. The P-electrode 114 covers nearly the entire surface of P-type semiconductor layer 104, between substrate 120 and the P-type semiconductor layer 104, and surrounds each of the plurality of N-electrodes 110. An insulating layer 108 electrically isolates the plurality of N-electrodes 110 and interconnect 112 from the P-type semiconductor layer 104, and the P-electrode 114. Each of the plurality of N-electrodes 110 are electrically coupled together by interconnect 112, and in turn interconnect 112 is electrically coupled to N-bond pads 122 (not shown). P-bond pads 124 are electrically coupled to the P-electrode 114. When packaged, the N-bond pads 122 and P-bond pads 124 provide the contact points for wire bonding to the power terminals of the completed LED assembly 100.

FIG. 1C shows the current spreading effect during device operation of the LED assembly 100 of FIG. 1A. Like FIG. 1A, FIG. 1C is a plan view of the LED assembly 100, particularly focusing on the LED 101. During device operation of the LED assembly 100, when power is applied to terminals of the LED assembly 100, a current will flow between the plurality of N-electrodes 110 and the P-electrode 114. Naturally, there will be a larger concentration of current around the plurality of N-electrodes 110, where the current is being injected. The higher concentration of current around the plurality of N-electrodes 110 will result in current crowding, decreasing the light output efficiency of the LED assembly 100. As the operating voltage of the LED assembly 100 increases, the current crowding effect will worsen, making the LED assembly 100 unsuitable for high-power applications.

As shown in FIG. 1C, current distribution 122 of the LED assembly 100 is uneven, and does not extend to outer sidewalls 118 of the LED 101. Uneven current distribution 122 will also negatively impact the light emission uniformity of the LED 101, with fewer photons being emitted by the light emitting layer 106 (shown in FIG. 1B) at the periphery of the LED 101 as a result of lower current concentration there.

There is, therefore, an unmet demand for LED assemblies with improved light output power, light output efficiency, and light emission uniformity, particularly for high-power applications.

### BRIEF DESCRIPTION OF THE INVENTION

In one embodiment, a light emitting diode (LED) assembly includes an LED comprising a light emitting layer disposed between a first layer having a first conductivity type and a second layer having a second conductivity type. In one embodiment, the first layer is a P-type semiconductor material and the second layer is an N-type semiconductor material. In another embodiment, the first layer is an N-type semiconductor material and the second layer is a P-type semiconductor material.

The LED assembly further includes a first electrode and a second electrode. The first electrode is formed on a surface of the first layer opposite the light emitting layer, and electrically coupled to the first layer. The first electrode substantially covers the surface of the first layer. The second electrode is formed at along a portion of the periphery of the LED outside of a perimeter of the first electrode. The second electrode extends through the first layer and the light emitting layer to the second layer, and is electrically coupled to the second layer. In one embodiment, the second electrode is formed inwards of a sidewall of the LED, between the first electrode and the sidewall. In one embodiment, an edge of the second electrode is formed to be contiguous with the sidewall of the LED. In one embodiment, the second electrode has a width between 5 μm and 10 μm. An insulating layer surrounds the second electrode to electrically isolate the second electrode from the first electrode and the first layer of the LED. The insulating layer may comprise any suitable dielectric material. In one embodiment, the insulating layer is a transparent material.

In another embodiment, the LED assembly includes one or more second electrodes along the periphery of the LED outside of the perimeter of the first electrode. In one embodiment, the one or more second electrodes are formed inwards of each sidewall of the LED, between the first electrode and the sidewall. In one embodiment, an edge of each of the one or more second electrodes is formed to be contiguous with each sidewall of the LED. In one embodiment, the one or more second electrodes partially surround the first electrode. In another embodiment, the one or more second electrodes completely surround the first electrode. In yet a further embodiment, the one or more second electrodes extend inwards of the sidewall of the LED.

In one embodiment, the LED assembly further includes one or more third electrodes formed through the first layer and the light emitting layer, and is electrically coupled to the second layer. The first electrode substantially surrounds the one or more third electrodes. Each of the one or more third electrodes is also surrounded by the insulating layer, between the third electrode and the first electrode, to electrically isolate the third electrode and the first electrode. In one embodiment, the first electrode, the one or more second electrodes, and the one or more third electrodes comprises a material with an optical reflectivity greater than 90% in the visible wavelength range. In one embodiment, the first electrode, the one or more second electrode, and the one or more third electrodes comprise silver (Ag).

In one embodiment, the LED assembly further includes a substrate having a first contact and a second contact. The first electrode is electrically coupled to the first contact, and the one or more second electrodes and the one or more third electrodes are electrically coupled to the second contact. During device operation, a voltage is applied to the first and second contacts of the LED assembly and the one or more second electrodes provide current injection enhancement along the periphery of the LED.

### BRIEF DESCRIPTION OF THE FIGURES

FIG. 1A shows a plan view of an LED assembly in the prior art.

FIG. 1B shows a cross-sectional view of the LED assembly of FIG. 1A.

FIG. 1C shows a current distribution during device operation of the LED assembly of FIG. 1A.

FIG. 2A shows a plan view of an LED assembly with current injection enhancement along a portion of the periphery of the LED, according to one embodiment of the invention.

FIG. 2B shows a cross-sectional view of the LED assembly of FIG. 2A.

FIG. 2C shows another cross-sectional view of the LED assembly of FIG. 2A, according to another embodiment of the invention.

FIG. 2D shows another cross-sectional view of the LED assembly of FIG. 2A.

FIG. 2E shows a current distribution during device operation of the LED assembly of FIG. 2A.

FIG. 3A shows a plan view of an LED assembly with current injection enhancement along the periphery of the LED, according to one embodiment of the invention.

FIG. 3B shows a cross-sectional view of the LED assembly of FIG. 3A.

FIG. 4 shows a plan view of an LED assembly with current injection enhancement along the periphery of the LED, according to another embodiment of the invention.

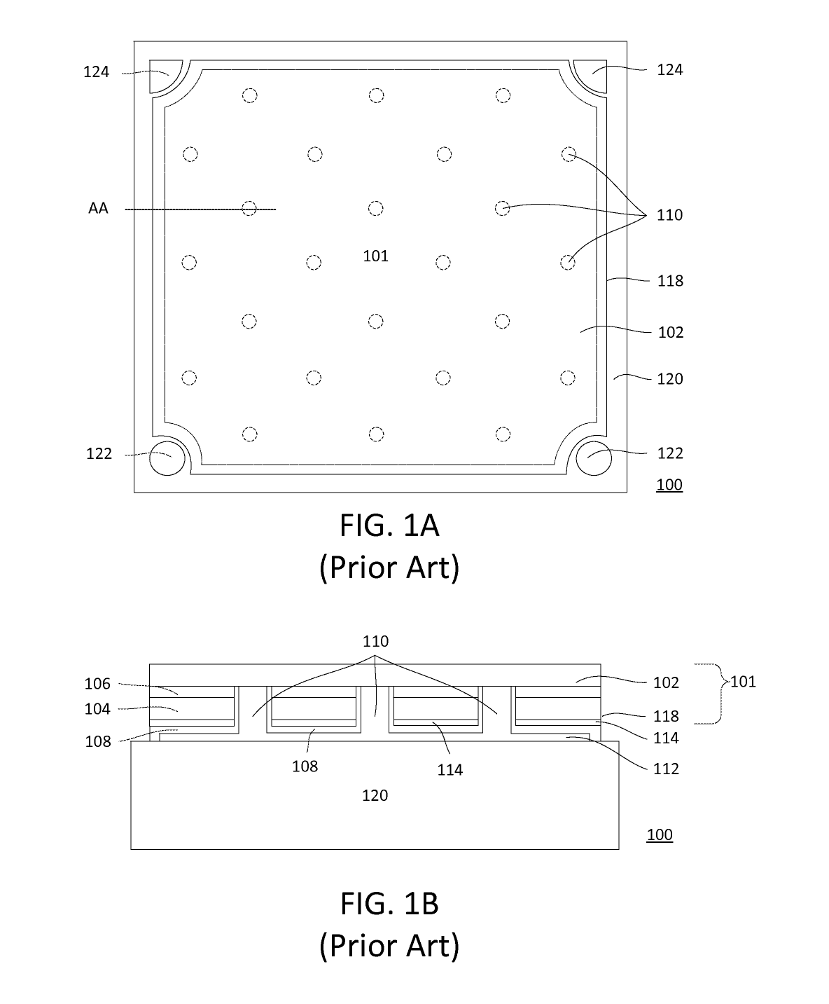

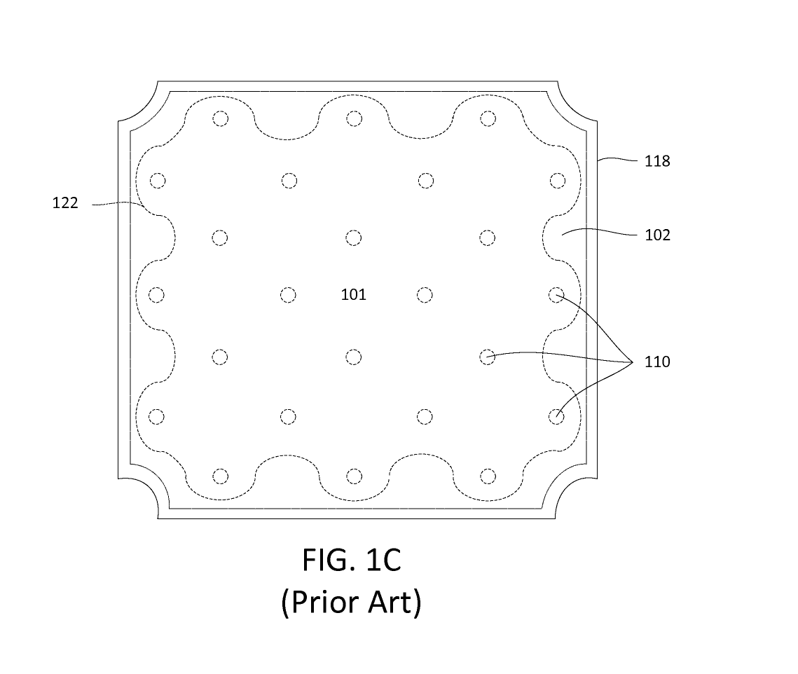

### DETAILED DESCRIPTION OF THE INVENTION

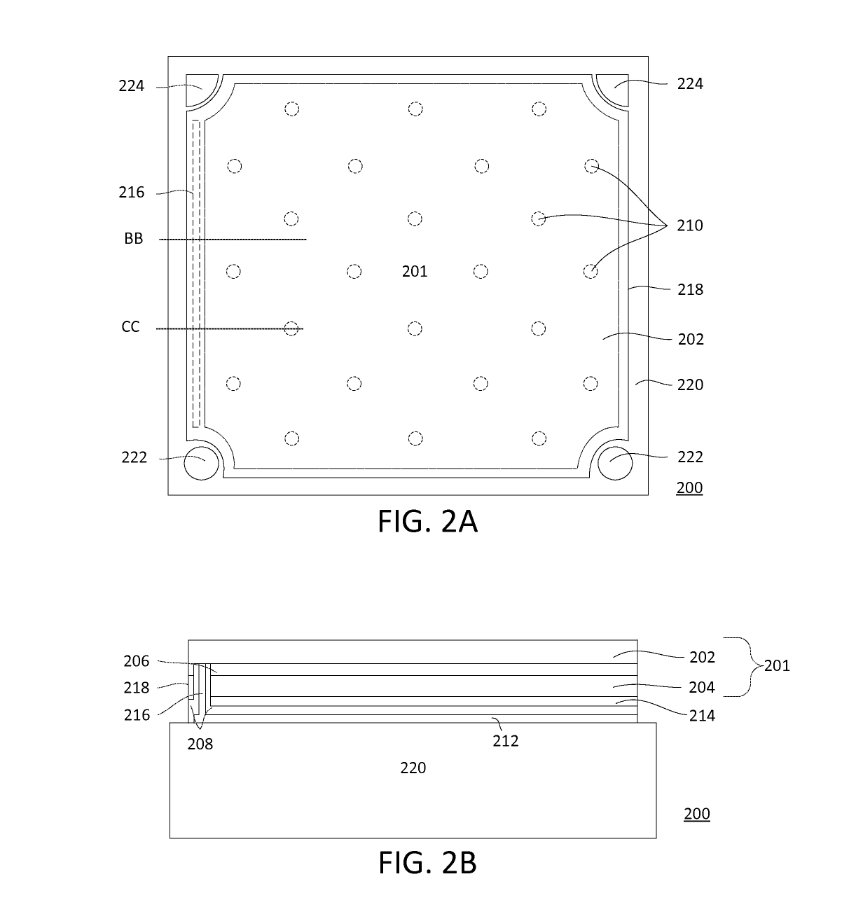

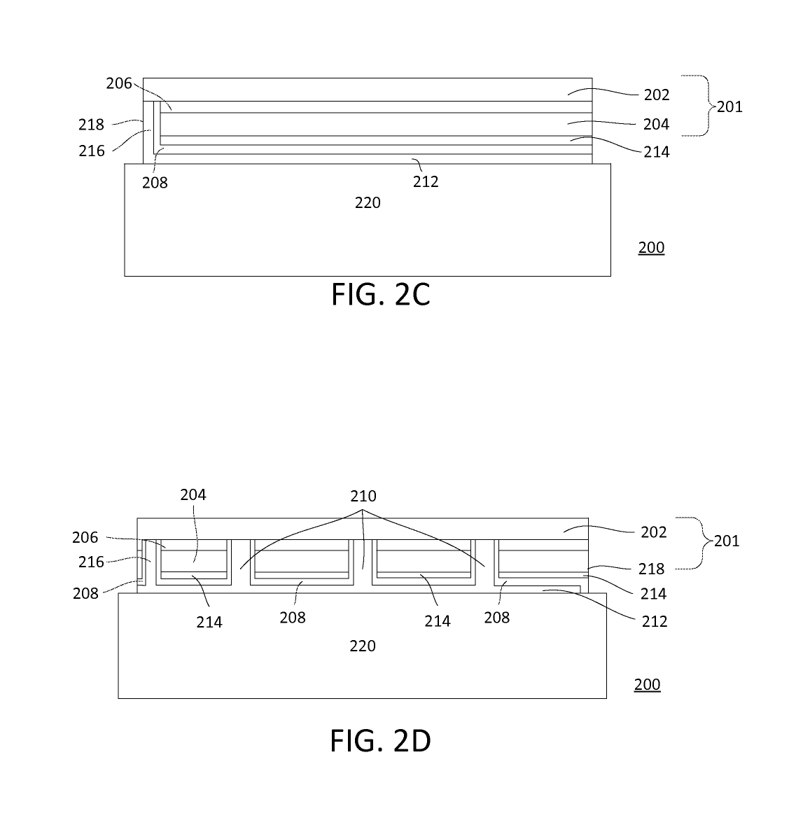

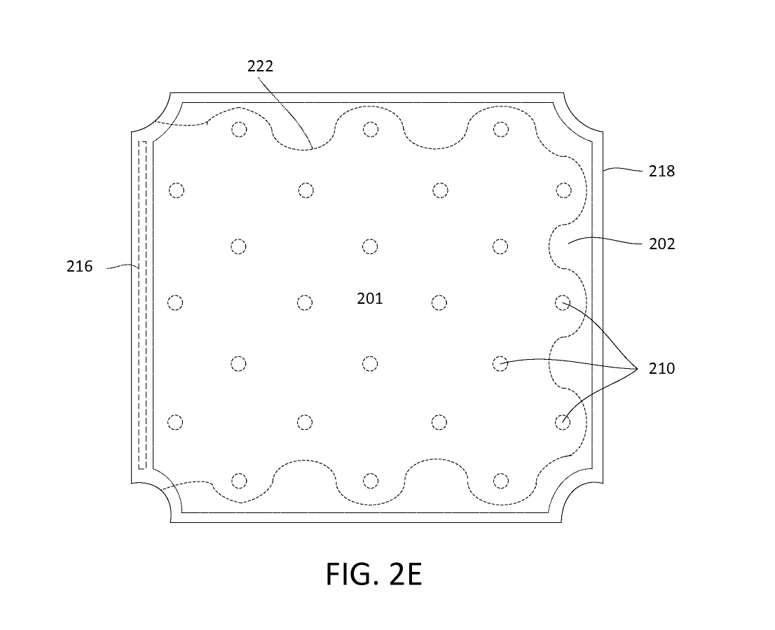

FIG. 2A shows a plan view of an LED assembly 200 with current injection enhancement along a portion of the periphery of the LED, according to one embodiment of the invention. FIG. 2B shows a cross-sectional view of the LED assembly 200 of FIG. 2A taken along the axis BB, and FIG. 2C shows the same cross-sectional view of the LED assembly 200 according to another embodiment of the invention. FIG. 2D shows a cross-sectional view of the LED assembly 200 of FIG. 2A taken along the axis CC. As shown in FIGS. 2A-D, an LED 201 comprises a light emitting layer 206 disposed between a first semiconductor layer 204 and the second semiconductor layer 202. The first semiconductor layer 204 and the second semiconductor layer 202 may comprise any suitable semiconductor material, for example, group III-V compounds such as gallium nitride (GaN), gallium arsenide (GaAs), gallium phosphide (GaP), indium phosphide (InP), or gallium arsenide phosphide (GaAsP). In one embodiment, the first semiconductor layer 204 comprises a P-type semiconductor material, and the second semiconductor layer 202 comprises an N-type semiconductor material. In another embodiment, the first semiconductor layer 204 comprises an N-type semiconductor material, and the second semiconductor layer 202 comprises a P-type semiconductor material.

A first electrode 214 is formed on a surface of the first semiconductor layer 204 opposite the light emitting layer 206, between substrate 220 and LED 201. The first electrode 214 substantially covers the surface of the first semiconductor layer 204, and is electrically coupled to the first semiconductor layer 204. Preferably the first electrode 214 comprises a highly reflective material to reflect photons which are emitted downwards from the light emitting layer 206 towards the substrate 220 so that the photons may escape the LED 201, improving the light output power and light output efficiency of the LED assembly 200. In one embodiment, the reflective material has an optical reflectivity greater than 90% in the visible wavelength range. In one embodiment, the first electrode 214 comprises silver (Ag).

A second electrode 216 is formed along a portion of the periphery of LED 201, outside of a perimeter of the first electrode 214. In one embodiment, as shown in FIGS. 2B and 2D, the second electrode 216 is formed inwards of the sidewall 218 of the LED 201, and is situated between the sidewall 218 and the first electrode 214. In another embodiment, as shown in FIG. 2C, the second electrode 216 may be formed to be contiguous with the sidewall 218 of the LED 201, where an outer edge of the second electrode 216 is flush with the sidewall 218.

A plurality of third electrodes 210 are formed in a patterned grid in the interior of the LED 201, and are surrounded by the first electrode 214. The second electrode 216 and the plurality of third electrodes 210 are both electrically coupled to second semiconductor layer 202 of the LED 201. The second electrode 216, as well as the plurality of third electrodes 210 extends through the first semiconductor layer 204 and the light emitting layer 206 in order to reach the second semiconductor layer 202 Like the first electrode 214, the second electrode 216 and plurality of third electrodes 210 may also comprise a highly reflective material, such as silver (Ag), to further reflect emitted photons from the light emitting layer 206.

Interconnect 212 electrically couples each of the plurality of third electrodes 210 and second electrode 216. An insulating layer 208 is formed around the second electrode 216, the plurality of third electrodes 210, and the interconnect 212 to electrically isolate these elements to prevent shorting with the first electrode 214 or the first semiconductor layer 204. Insulating layer 208 is preferably transparent to prevent the absorption of emitted photons from the light emitting layer 206, reducing the overall light output power and light output efficiency of the LED assembly 200. In one embodiment, the insulating layer 208 comprises silicon dioxide (SiO₂). In other embodiments, the insulating layer 208 can be silicon nitride (Si₃N₄), aluminum oxide (Al₂O₃), titanium oxide (TiO₂), or any other suitable transparent dielectric material.

First bond pads 224 are electrically coupled to the first electrode 214, and second bond pads 222 are electrically coupled to the second electrode 216, the plurality of third electrodes 210, and the interconnect 212. When packaged, the first bond pads 224 and second bond pads 222 provide the contact points for wire bonding to the power terminals of the LED assembly 200. By forming the second electrode 216 along a portion of the periphery of the LED 201, the second electrode 216 provides additional current injection at that region of the LED 201 during device operation of the LED assembly 200 when power is applied to the first and second bond pads 224 and 222. The additional current injection provided by the second electrode 216 yields improved current spreading and uniformity at the periphery of the LED 201 as shown in FIG. 2E.

FIG. 2E shows a current distribution 222 during device operation of the LED assembly of FIG. 2A. In FIG. 2E, the current distribution 222 along the left periphery of the LED 201 extends to the sidewall of the LED 201 as a result of the enhanced current injection from the second electrode 216. The increased current injection at the left periphery will improve the light emission uniformity in this region of the LED 201 as the current distribution 222 in this region is much more uniform, resulting in uniform photon generation by the light emitting layer 206 extending to the left periphery of the LED 201.

Compared with the other periphery regions of the LED 201 without increased current injection at those regions, the left periphery will exhibit increased light output power and light output efficiency, particularly at higher operating voltages where the increased current flow between the first electrode 214 and the second electrode 216 and the plurality of third electrodes 210 will result in current crowding effects around the second electrode 216 and the plurality of third electrodes 210. This is true even though a portion of the light emitting layer 206 must be sacrificed in order to form the second electrode 216 (recall the second electrode 216 must extend through the first semiconductor layer 204 and the light emitting layer 206 to reach the second semiconductor layer 202 as discussed in connection with FIGS. 2A-D). In one embodiment, to minimize the amount of light emitting layer 206 that must be removed to form the second electrode 216, the second electrode 216 has a width between 5 μm and 10 μm.

The second electrode 216 maintains uniformity in the current distribution 222 at the left periphery of the LED 201 so that even at high current, the photon emission of the light emitting layer 206 at the left periphery of the LED 201 is comparable to that of the photon emission at the center of the LED 201 surrounded by the plurality of the third electrodes 210. In other words, even though there is less area for light generation to occur in the left periphery of the LED 201 due to the second electrode 216, more photons will be generated because of the enhanced current injection in this region, resulting in a net increase in light output power. In contrast, the upper, lower, and right periphery regions of the LED 201 have reduced photon emission compared to the center of the LED 201 as a result of lower current density in those periphery regions despite having more light emitting area. As the operating voltage of the LED assembly 200 increases, the difference between the light output power, light output efficiency, and the light emission efficiency of the left periphery of the LED 201 with enhanced current injection from the second electrode 216 and the other periphery regions will correspondingly increase as well, as the relative current density of the periphery regions without enhanced current injection will decrease due to increasing current crowding effects at higher currents.

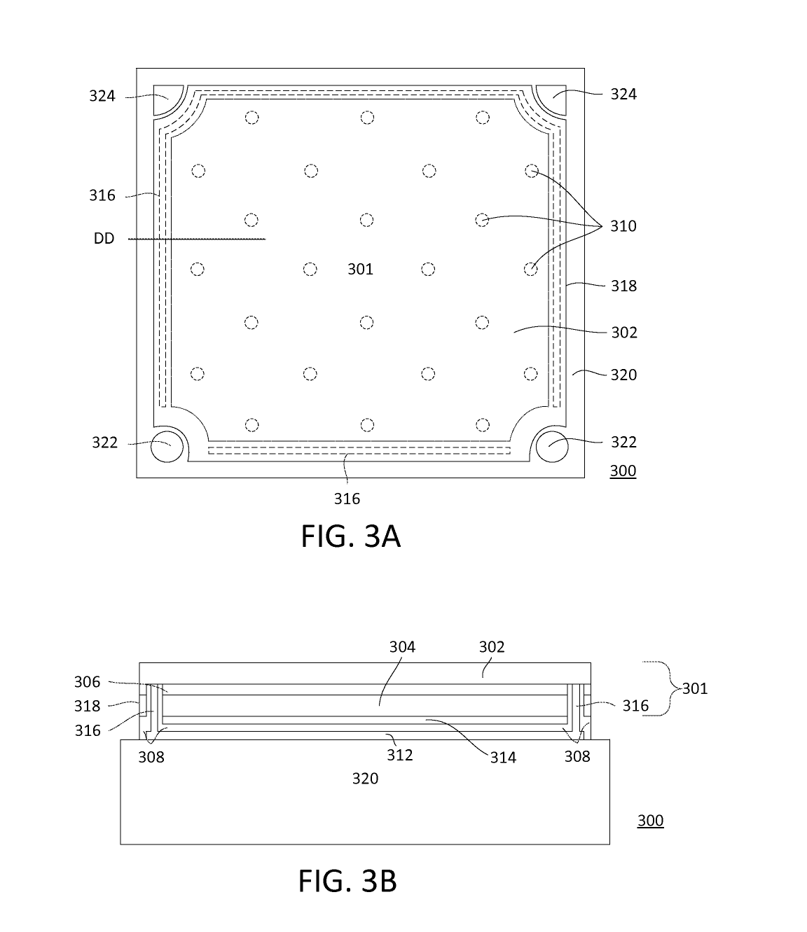

FIG. 3A shows a plan view of an LED assembly 300 with current injection enhancement along the periphery of the LED, according to one embodiment of the invention. FIG. 3B shows a cross-sectional view of the LED assembly 300 of FIG. 3A. taken along the axis CC. As shown in FIGS. 3A and 3B, LED 301 comprises a light emitting layer 306 disposed between a first semiconductor layer 304 and the second semiconductor layer 302. Similar to the LED assembly 200 shown and described in FIGS. 2A-C, above, the first semiconductor layer 304 and the second semiconductor layer 302 may comprise any suitable semiconductor material such as gallium nitride (GaN) or any other group III-V compound. In one embodiment, the first semiconductor layer 304 comprises a P-type semiconductor material, and the second semiconductor layer 302 comprises an N-type semiconductor material. In another embodiment, the first semiconductor layer 304 comprises an N-type semiconductor material, and the second semiconductor layer 302 comprises a P-type semiconductor material.

A first electrode 314 is formed on a surface of the first semiconductor layer 304 opposite the light emitting layer 306, between the LED 301 and the substrate 320. The first electrode 314 substantially covers the surface of the first semiconductor layer 304, and is electrically coupled to the first semiconductor layer 304. Second electrodes 316 are formed along the periphery of LED 301. The second electrodes 316 are situated outside of the perimeter of the first electrode 314. The second electrodes 316 are formed inwards of sidewalls 318 of the LED 301, between the sidewalls 318 and first electrode 314. In one embodiment, the second electrodes 316 are formed to be contiguous with the sidewall 318 of the LED 301. The second electrodes 316 partially surround the first electrode 314. In one embodiment, second electrodes 316 comprise one continuous electrode extending along the periphery of the LED 301. In another embodiment, second electrodes 316 comprise one continuous electrode along the periphery of the LED 301 that completely surrounds the first electrode 314. In yet another embodiment, second electrodes 316 comprise a plurality of electrodes at each peripheral region around the LED 301.

A plurality of third electrodes 310 are formed in a patterned grid in the interior of the LED 301, and are surrounded by the first electrode 314. The second electrodes 316 and the plurality of third electrodes 310 are both electrically coupled to second semiconductor layer 302 of the LED 301. Interconnect 312, in turn, electrically couples each of the plurality of third electrodes 310 and second electrodes 316. Insulating layer 308 surrounds the second electrodes 316 and third electrodes 310, and electrically isolates these elements from the first electrode 314 and the first semiconductor layer 304. Again, similar to the LED assembly 200 of FIGS. 2A-D discussed above, in various embodiments the first electrode 314, the second electrodes 316, and the third electrodes 310 may each comprise a highly reflective material, capable of reflecting greater than 90% of visible light, and the insulating layer 308 may comprise a transparent insulating material, such as silicon dioxide (SiO₂) or any other suitable dielectric material. In one embodiment, the second electrodes 316 have a width between 5 μm and 10 μm. First bond pads 324 are electrically coupled to the first electrode 314, and second bond pads 322 are electrically coupled to the second electrodes 316, the plurality of third electrodes 310, and interconnect 312. When packaged, the first bond pads 324 and second bond pads 322 provide the contact points for wire bonding to the power terminals of the completed LED assembly 300.

By forming second electrodes 316 along the periphery of the LED 301, between the sidewall 318 and the first electrode 314, second electrodes 316 will provide enhanced current injection at the periphery of the LED 301 during device operation of the LED assembly 300. As previously discussed, the enhanced current injection from the second electrodes 316 will create a relatively uniform current distribution that spreads to the periphery of LED 301, yielding an increase in the overall light output power due to an increase in photon emission at the periphery of the LED 301 despite the loss of light emitting area as a result of forming the second electrodes 316. Uniform current distribution throughout the LED 301 in turn will result in improved light emission uniformity from the light emitting layer 306.

The LED assembly 300 is particularly well suited for high voltage operation, as the second electrodes 316 provide enhanced current injection along the periphery of the LED 301 to counteract against current crowding effects at higher operating currents. In practical application, the LED assembly 300 will realize a 5-6% increase in wall-plug efficiency as compared to similarly sized conventional LED assemblies without current injection enhancement along the periphery of the LED. The wall-plug efficiency of an LED assembly represents the energy conversion efficiency with which the LED assembly converts electrical power into optical power, i.e. light.

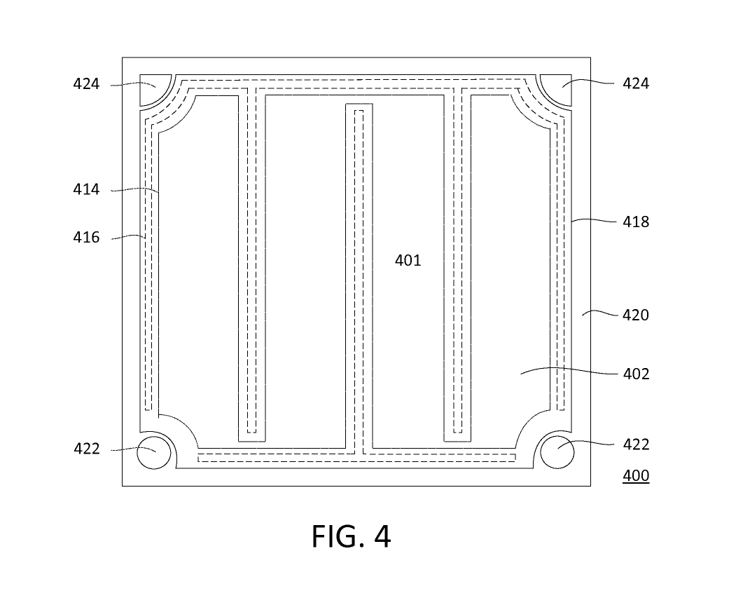

FIG. 4 shows a plan view of an LED assembly with current injection enhancement along the periphery of the LED, according to another embodiment of the invention. In FIG. 4, a first electrode 414 is again formed between LED 401 and substrate 420. However, as shown in FIG. 4, second electrodes 416 are situated along the periphery of the LED 401, and extend into the LED 401, partially surrounding the first electrode 414. In one embodiment, second electrodes 416 comprise one continuous electrode along the periphery of the LED 401 and extending into the LED 401, completely surrounding the first electrode 414. In yet another embodiment, second electrodes 416 comprise a plurality of electrodes at each peripheral region around the LED 401 and extending into the LED 401.

The LED assembly 400 will similarly exhibit improved light output power, light output efficiency, and light emission uniformity as the LED assembly 300 discussed and illustrated in FIG. 3A and 3B, above, as a result of the enhanced current injection from the second electrodes 416 around the periphery of the LED 401.

Other objects, advantages and embodiments of the various aspects of the present invention will be apparent to those who are skilled in the field of the invention and are within the scope of the description and the accompanying Figures. For example, but without limitation, structural or functional elements might be rearranged consistent with the present invention. Similarly, principles according to the present invention could be applied to other examples, which, even if not specifically described here in detail, would nevertheless be within the scope of the present invention.

1. A light emitting diode (LED) assembly comprising:
an LED comprising a light emitting layer disposed between a first layer having a first conductivity type and a second layer having a second conductivity type;
a first electrode formed on a surface of the first layer opposite the light emitting layer, the first electrode substantially covers the surface of the first layer and electrically coupled to the first layer;
a second electrode formed along a portion of the periphery of the LED outside of a perimeter of the first electrode, the second electrode extending through the first layer and the light emitting layer, wherein the second electrode is in contact with a surface of the second layer facing the light emitting layer and electrically coupled to the second layer.

2. The LED assembly of claim 1, wherein the second electrode is formed inwards of a sidewall of the LED, between the first electrode and the sidewall.

3. The LED assembly of claim 1, wherein an edge of the second electrode is formed to be contiguous with a sidewall of the LED.

4. The LED assembly of claim 1, wherein the second electrode is between 5 μm and 10 μm in width.

5. The LED assembly of claim 1, further comprising one or more third electrodes formed through the first layer and the light emitting layer, wherein the one or more third electrodes is in contact with the surface of the second layer facing the light emitting layer and electrically coupled to the second layer, and
the first electrode substantially surrounds the one or more third electrodes.

6. The LED assembly of claim 5, wherein the first electrode completely surrounds the one or more third electrodes.

7. The LED assembly of claim 5, further comprising an insulating layer formed between the second electrode and the one or more third electrodes, and the first electrode,
wherein the insulating layer electrically isolates the first electrode from the second electrode and the one or more third electrodes.

8. The LED assembly of claim 5, further comprising a substrate having a first contact and second contact,
wherein the first electrode is electrically coupled to the first contact, and the second electrode and the one or more third electrodes are electrically coupled to the second contact.

9. The LED assembly of claim 5, wherein the first electrode, the second electrode, and the one or more third electrodes comprises a material having a high degree of reflectivity.

10. The LED assembly of claim 9, wherein the material is Ag.

11. A light emitting diode (LED) assembly comprising:
an LED comprising a light emitting layer disposed between a first layer having a first conductivity type and a second layer having a second conductivity type;
a first electrode formed on a surface of the first layer opposite the light emitting layer, the first electrode substantially covers the surface of the first layer and electrically coupled to the first layer;
one or more second electrodes formed along the periphery of the LED, outside of a perimeter of the first electrode and partially surrounding the first electrode, the one or more second electrodes extending through the first layer and the light emitting layer, wherein the one or more second electrodes are in contact with a surface of the second layer facing the light emitting layer and electrically coupled to the second layer.

12. The LED assembly of claim 11, wherein the one or more second electrodes completely surrounds the first electrode.

13. The LED assembly of claim 11, wherein the one or more second electrodes are formed inwards of each sidewall of the LED device, between the first electrode and the sidewall.

14. The LED assembly of claim 11, wherein an edge of each of the one or more second electrodes is formed to be contiguous with each sidewall of the LED.

15. The LED assembly of claim 11, wherein each of the one or more second electrodes has a width between 5 μm and 10 μm.

16. The LED assembly of claim 11, further comprising one or more third electrodes formed through the first layer and the light emitting layer, wherein the one or more third electrodes is in contact with the surface of the second layer facing the light emitting layer and electrically coupled to the second layer, and
the first electrode substantially surrounds the one or more third electrodes.

17. The LED assembly of claim 11, wherein the first electrode completely surrounds the one or more third electrodes.

18. The LED assembly of claim 16, further comprising an insulating layer formed between the one or more second electrodes and the one or more third electrodes, and the first electrode,
wherein the insulating layer electrically isolates the first electrode from the one or more second electrodes and the one or more third electrodes.

19. The LED assembly of claim 16, further comprising a substrate having a first contact and second contact,
wherein the first electrode is electrically coupled to the first contact, and the one or more second electrodes and the one or more third electrodes are electrically coupled to the second contact.

20. The LED assembly of claim 16, wherein the first electrode, the one or more second electrodes, and the one or more third electrodes comprises a material having a high degree of reflectivity.

21. The LED assembly of claim 20, wherein the material is Ag.

22. The LED assembly of claim 1, wherein the LED is a singulated LED.

23. The LED assembly of claim 11, wherein the LED is a singulated LED.
